(19) United States
(12) Patent Application Publication
(10) Pub. No.: US 2014/0065834 A1
(43) Pub. Date: Mar. 6, 2014

(54) METHOD OF MANUFACTURING MOLD FOR NANO-IMPRINT AND SUBSTRATE FABRICATING METHOD

(71) Applicant: Shuji Kishimoto, Shinjuku-ku (JP)

(72) Inventor: Shuji Kishimoto, Shinjuku-ku (JP)

(73) Assignee: HOYA CORPORATION, Shinjuku-ku, Tokyo (JP)

(21) Appl. No.: 14/005,671

(22) PCT Filed: Mar. 23, 2012
(86) PCT No.: PCT/JP2012/057517

§ 371 Date: Nov. 5, 2013

(30) Foreign Application Priority Data
Mar. 25, 2011 (JP) 2011-067413

(51) Int. Cl. H01L 21/308

(52) U.S. Cl. CPC H01L 21/3083
USPC 438/706

(57) ABSTRACT

Provided is a method of manufacturing a mold for nano-imprint, for forming a projection/recess pattern on a surface of a silicon substrate, including: etching a substrate to form the projection/recess pattern on the surface of the silicon substrate by applying dry-etching to the silicon substrate using a hard mask pattern as a mask, in a state of covering the surface of the silicon substrate with the hard mask pattern made of a chromium-based material; and applying dry-etching to the silicon substrate in etching the substrate using a fluorine-based gas as a reactive gas of an etching gas used for the dry-etching applied to the silicon substrate, and adding an inert gas to the etching gas.

### TECHNICAL FIELD

The present invention relates to a method of manufacturing a mold for nano-imprint and a substrate fabricating method, and more specifically relates to the method for manufacturing a mold for nano-imprint and the substrate fabricating method applied to a case that a silicon substrate having a projection-recess pattern.

### DESCRIPTION OF RELATED ART

As a method of forming the projection/recess pattern on the silicon substrate, the following method is known. First, a resist pattern is formed on the silicon substrate interposing a hard mask. Next, a hard mask pattern is formed by patterning the hard mask layer using this resist pattern as a mask. Next, etching is applied to the silicon substrate using this hard mask pattern as the mask.

When such a projection/recess pattern is formed on the silicon substrate by the above-mentioned method, a technique of using a silicon oxide film as a hard mask layer, is known (for example, see patent document 1). However, when the hard mask layer is formed by the silicon oxide film, an etching selectivity of a hard mask material to silicon cannot be largely secured.

Further conventionally, when etching is applied to the silicon oxide film, the technique of using chromium and chromium alloy as the mask material for etching, is proposed (for example, see patent documents 2 and 3).

### PRIOR ART DOCUMENT

### Patent document

Patent document 1: Japanese Patent Laid Open Publication No. 2000-208484

Patent document 2: Japanese Patent Laid Open Publication No. 1994-2991090

Patent document 3: Japanese Patent Laid Open Publication No. 2003-86513

### SUMMARY OF THE INVENTION

### Problem to be solved by the Invention

Generally, when the projection/recess pattern is formed on the silicon substrate, the hard mask layer can be made thin and a finer pattern and high precision can be achieved by forming the hard mask layer with a metal film such as chromium, compared with a case that the silicon oxide film is used. However, when dry-etching is applied to the silicon substrate using the hard mask pattern as the mask, a side face of the pattern formed on the silicon substrate is formed into a “bowing shape” in some cases. The bowing shape is the shape defined as follows. Namely, when a circular hole pattern having a sectional recess shape is formed by applying etching to a surface of silicon, the bowing shape is the shape in which a hole diameter of an intermediate depth portion of this circular hole pattern is large compared with the hole diameter (opening diameter) of an inlet portion of this circular hole pattern. Further, when a groove pattern having the sectional recess shape is formed by applying etching to the surface of silicon, the bowing shape is the shape in which a groove width of the intermediate depth portion of this groove pattern is wide compared with the groove width of the inlet portion of this groove pattern.

A main reason for forming the side face of the pattern formed on the silicon substrate, into the bowing shape, is that silicon is side-etched under the hard mask pattern with a progress of etching isotropically applied to silicon. Specifically, for example, when etching is applied to silicon using fluorine-based gas, etching to silicon is progressed isotropically depending on a setting of a process pressure (pressure in an etching chamber). Therefore, silicon is side-etched, and the side face of the pattern finally obtained is formed into the bowing shape. In order to avoid such a sate, if the process pressure is lowered, (1) the etching selectivity of the mask material and silicon becomes smaller, and (2) the etching rate for silicon is lowered. Above all, the disadvantage described in (1) causes an inconvenience that the hard mask pattern disappears when etching is applied to the silicon substrate at a high aspect ratio (called a deep-digging etching hereafter). Also, the disadvantage described in (2) causes an inconvenience of reducing productivity due to a prolonged time required for the etching applied to the silicon substrate.

Further, in a deep-digging etching applied to the silicon substrate, an important subject is to suppress a side etching for maintaining a verticality of the side face of the pattern. An influence of the side etching becomes particularly large when manufacturing the mold (master disc) for imprint which is required to form a fine pattern with high precision. The following circumstance is the reason thereof. Namely, in an imprint method, resist is cured by heat application or light irradiation for example, with the pattern of the mold pushed against a resist layer in an uncured state formed on a transfer substrate. At this time, the resist filled into a dent portion of the pattern by press of the mold, is cured following the shape of this pattern. Therefore, when the side face of the pattern of the mold has the bowing shape, the resist is held in the pattern of the mold when the mold is peeled-off from the transfer substrate after curing of the resist, and it becomes difficult to separate the mold from the transfer substrate. Even if the mold can be separated from the transfer substrate, there is a risk of a collapse of the shape of the pattern or damage of the pattern itself.

A main object of the present invention is to provide a technique of obtaining a high verticality of the side face of the pattern even if the process pressure is not lowered, when a projection/recess pattern is formed on the surface of the silicon substrate by dry etching using the hard mask pattern.

### SUMMARY OF THE INVENTION

According to a first aspect of the present invention, there is provided a method of manufacturing a mold for nano-imprint, for forming a projection/recess pattern on a surface of a silicon substrate, including:
etching a substrate to form the projection/recess pattern on the surface of the silicon substrate by applying dry-etching to the silicon substrate using a hard mask pattern as a mask, in a state of covering the surface of the silicon substrate with the hard mask pattern made of a chromium-based material; and
applying dry-etching to the silicon substrate in etching the substrate using a fluorine-based gas as a reactive gas of an etching gas used for the dry-etching applied to the silicon substrate, and adding an inert gas to the etching gas.

According to a second aspect of the present invention, there is provided the method of manufacturing a mold for nano-imprint according to the first aspect, wherein in etching the substrate, the inert gas is added so that a side face of a pattern obtained by applying dry-etching to the silicon substrate, is not formed into a bowing shape.

According to a third aspect of the present invention, there is provided the method of manufacturing a mold for nano-imprint according to the first or second aspect, wherein a flow rate of the inert gas is set in a range of 4 to 10 times of the flow rate of the fluorine-based gas.

According to a fourth aspect of the present invention, there is provided the method of manufacturing a mold for nano-imprint according to any one of the first to third aspects, wherein in etching the substrate, dry-etching is applied to the silicon substrate in a state of lowering a partial pressure of the fluorine-based gas by adding the inert gas to the etching gas while maintaining a process pressure to be constant.

According to a fifth aspect of the present invention, there is provided a substrate fabricating method, including:
etching a substrate for forming a projection/recess pattern on a surface of a silicon substrate, by applying dry-etching to the silicon substrate using a hard mask pattern as a mask in a state of covering the surface of the silicon substrate with the hard mask pattern; and
applying dry-etching to the silicon substrate in a state that a partial pressure of a fluorine-based gas is lowered by adding the inert gas to an etching gas compared with a case that an inert gas is not added, using the fluorine-based gas as a reactive gas of the etching gas used for the dry-etching applied to the silicon substrate.

### ADVANTAGE OF THE INVENTION

According to the present invention, when the projection/recess pattern is formed on the surface of the silicon substrate by applying dry-etching thereto using the hard mask pattern, the verticality of the side face of the pattern can be increased even if not lowering the process pressure.

### BRIEF DESCRIPTION OF THE DRAWINGS

FIG. 1 is a flowchart showing a basic procedure of a substrate fabricating method according to an embodiment of the present invention.

FIG. 2 is a view (view 1) showing a processing content of each step of the substrate fabricating method according to an embodiment of the present invention.

FIG. 3 is a view (view 2) showing the processing content of each step of the substrate fabricating method according to an embodiment of the present invention.

FIG. 4 is a view showing a shape of a pattern obtained by a test result.

FIG. 5 is a view showing a relation between a mixing ratio of an etching gas and an etching rate.

### MODE FOR CARRYING OUT THE INVENTION

Modes for carrying out the invention will be described hereafter, with reference to the drawings.

Embodiments of the present invention will be described in the following order.

1. Basic procedure of a substrate fabricating method

2. Explanation for characteristic step

3. Test result

4. Effect of an embodiment

5. Modified example, etc.

### 1. Basic Procedure of a Substrate Fabricating Method

First, a basic procedure of a substrate fabricating method according to an embodiment of the present invention will be described.

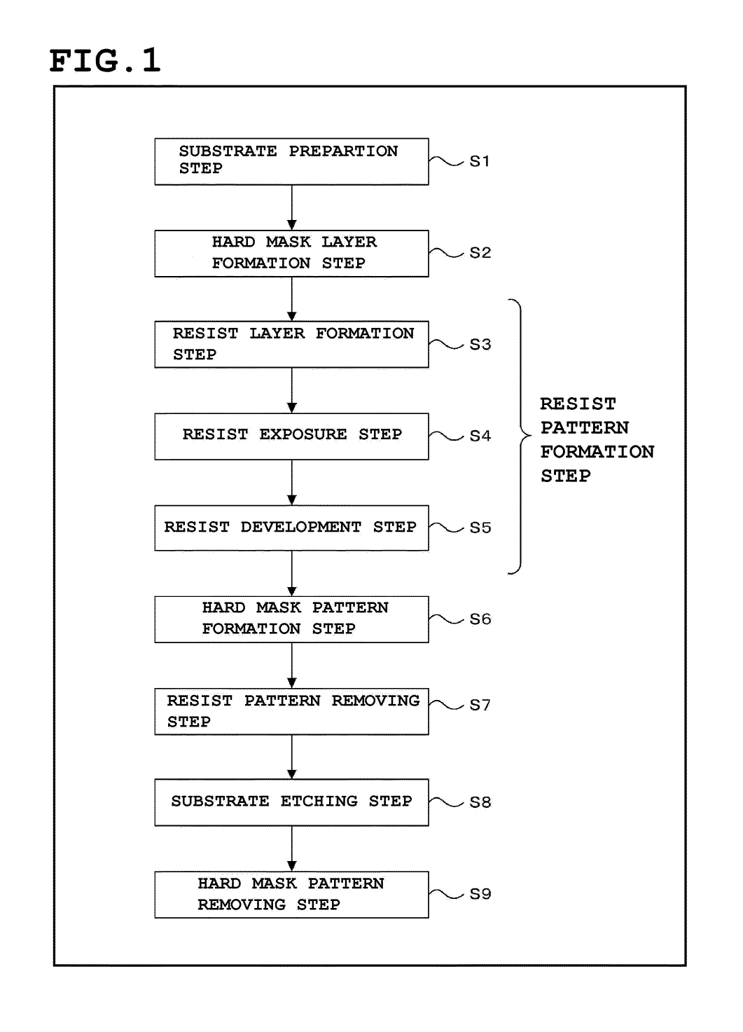

As shown in FIG. 1, the substrate fabricating method according to the embodiment of the present invention is roughly includes a substrate preparation step S1, a hard mask layer formation step S2, a resist layer formation step S3, a resist exposure step S4, a resist development step S5, a hard mask pattern formation step S6, a resist pattern removing step S7, a substrate etching step S8, and a hard mask pattern removing step S9.

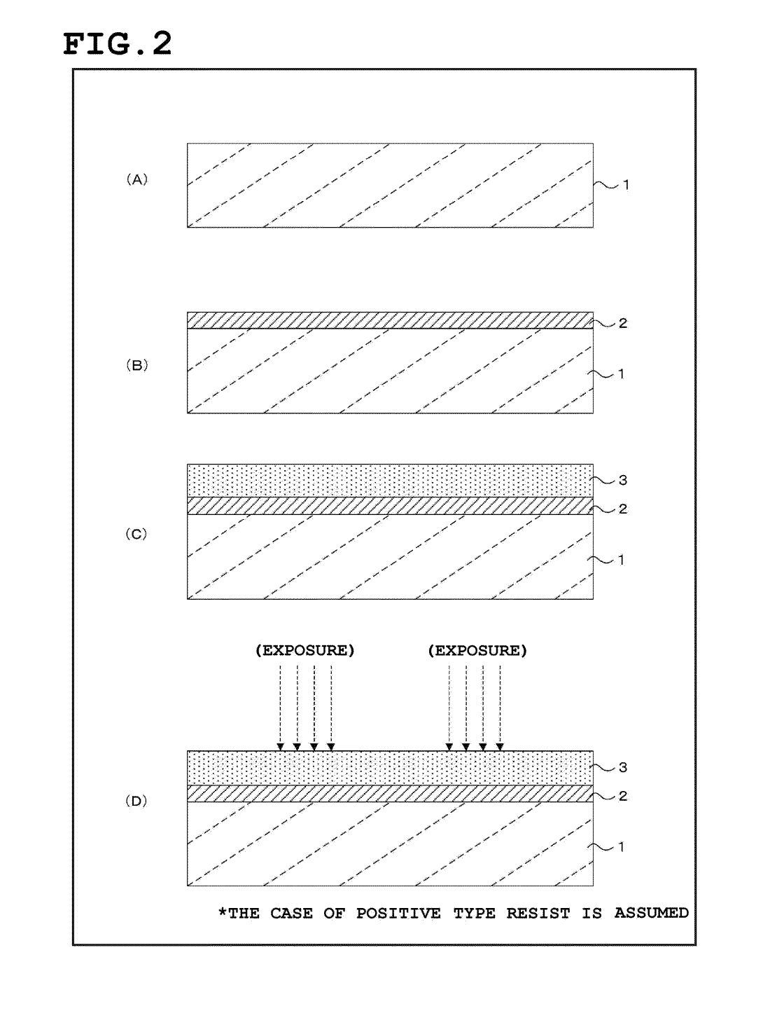

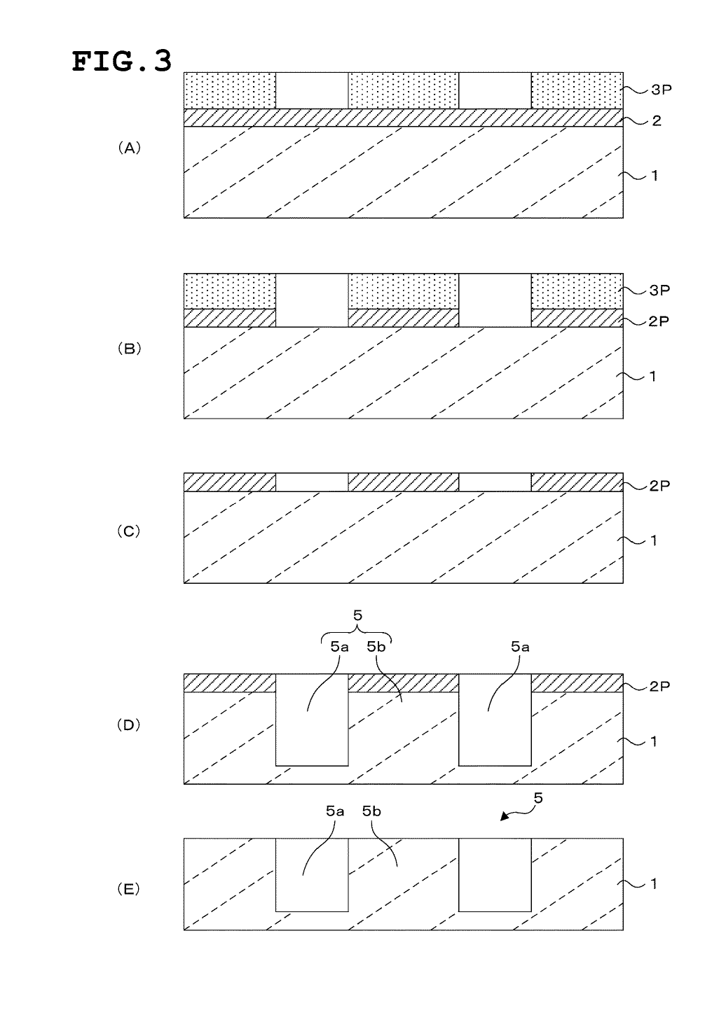

Each step will be described hereafter using FIG. 2 and FIG. 3.

(Substrate Preparation Step S1)

First, as shown in FIG. 2A, a silicon substrate 1 being a processing object, is prepared. The silicon substrate 1 is a circular flat substrate in plan view, and has a thickness capable of exhibiting a moderate rigidity. Therefore, the silicon substrate 1 is the substrate having two main surfaces and an end face excluding such two main surfaces. The main surface of the silicon substrate 1 is the surface that exists one by one in a thickness direction of the silicon substrate 1 and in the other direction thereof in a relation of front and rear. The end face of the silicon substrate 1 is the surface vertical to the main surface of the silicon substrate 1. The substrate fabricating method of the present invention is the method of applying etching to silicon itself which is a constitutional material of the silicon substrate 1 in the substrate etching step S8 as described later.

(Hard Mask Layer Formation Step S2)

Next, as shown in FIG. 2B, a hard mask layer 2 is formed on the silicon substrate 1. In this case, the hard mask layer 2 is formed on one of the main surfaces of the silicon substrate 1. Specifically, the hard mask layer 2 is formed so as to cover a surface of the silicon substrate 1, on one of the main surfaces of the silicon substrate 1. The surface of the silicon substrate 1 described here, means the surface made of silicon in which almost no silicon oxide is contained. However, without particular intention, a thin silicon oxide film (natural oxide film) is formed on the surface of the silicon by which the silicon substrate 1 is formed, by bond with oxygen that exists in the atmosphere and an etching chamber. In this case, the silicon oxide film covering the surface of the silicon substrate 1 becomes an extremely thin film. Therefore, when etching is started to the silicon substrate 1 in the substrate etching step S8 as described later, the silicon oxide film is removed immediately, and subsequently etching is applied to silicon. Accordingly, the substrate fabricating method of this embodiment is applied not only to a case that the surface of the silicon substrate 1 is made of silicon only, but also to a case that a silicon surface is covered with the above-mentioned thin silicon oxide film, or a case that the silicon surface is covered with a thin film which does not cause any trouble in etching.

The hard mask layer 2 is a base of a mask pattern when etching is applied to the silicon substrate 1 in the substrate etching step S8 as described later. The hard mask layer 2 is formed using a hard mask material. As the hard mask material, a metal (including alloy) material can be used. Specifically, for example, chromium or chromium alloy (as an example, chromium nitride) can be suitably used. Further, formation of the hard mask layer 2 can be performed using a sputtering method. In this case, a thickness of the hard mask layer 2 is preferably formed to be thin as much as possible in consideration of a precision of a projection/recess pattern which is formed finally on the silicon substrate 1. Specifically, the thickness is set to 5 nm or less.

(Resist Layer Formation Step S3)

Next, as shown in FIG. 2C, a resist layer 3 is formed on the silicon substrate 1, in a state of covering the hard mask layer 2. Formation of the resist layer 3 is performed using a spin-coat method for example. A general material (specifically ZEP520A by ZEON CORPORATION) can be used as a resist material for electron beam lithography, like the resist material including a polymer of methyl α-chloroacrylate and α-methyl styrene. Then, such a resist material is used to form a film on an upper surface of the hard mask layer 2, into a specific thickness by the spin-coat method. Then by applying baking thereto, the resist layer 3 is formed. The thickness of the resist layer 3 is set to the thickness allowing the resist layer 3 (resist pattern 3P) to be remained until completion of the etching, when etching is applied to the hard mask layer 2 in the hard mask pattern formation step S6 as described later.

(Resist Exposure Step S4)

Next, exposure and development of the resist layer are sequentially performed as the processing for patterning the resist layer 3. Specifically, as shown in FIG. 2D, the resist layer 3 on the silicon substrate 1 is exposed by irradiation of an electron beam. In the resist exposure step S4, for example, the resist layer is exposed according to a prescribed pattern, by irradiating a specific part of the resist layer 3 with the electron beam using an electron beam lithograph apparatus. In this case, when the resist layer 3 is formed using a positive-type resist material, a portion irradiated with the electron beam (exposure portion) is solubilized. Further, when the resist layer 3 is formed using a negative-type resist material, the portion irradiated with the electron beam is insolubilized. In this embodiment, as an example, the resist layer 3 is formed using the positive-type resist material.

(Resist Exposure Step S5)

Next, as shown in FIG. 3A, a resist pattern 3P is formed by developing the resist layer 3 on the silicon substrate 1. In the resist development step S5, for example, an exposed portion of the resist layer 3 is dissolved and removed by a developing agent, by supplying the developing agent to the exposed resist layer 3. As the developing agent, for example, a solution containing a solvent composed of fluorocarbon (specifically, Vertrel XF (registered trademark) by MITSUI DUPON FLOROCHEMICAL CORPORATION), a solution containing a solvent composed of acetic acid-n-amyl, ethyl acetate or a mixture of them (specifically, ZED-N50 (by ZEON CORPORATION) can be used. Thus, there is a state that the resist pattern 3P is formed on the silicon substrate 1 interposing the hard mask layer 2.

In the explanation hereafter, the formation step of the resist pattern 3P including the resist layer formation step S3, the resist exposure step S4 and the resist development step S5, is described as a “resist pattern formation step”.

(Hard Mask Pattern Formation Step S6)

Next, as shown in FIG. 3B, a hard mask pattern 2P is formed by etching the hard mask layer 2 using the resist pattern 3P as a mask. In the hard mask pattern formation step S6, for example, a hard mask pattern can be formed using a mixed gas of a chlorine gas and an oxygen gas when the hard mask layer 2 is a metal film composed of chromium or chromium alloy. Thus, a portion not covered with the resist pattern 3P of the hard mask layer 2, is removed. Therefore, the hard mask layer 2 is patterned following a pattern shape of the resist pattern 3P. As a result, the following state is formed. Namely the hard mask pattern 2P and the resist pattern 3P are formed on the silicon substrate 1 in an overlapped appearance.

(Resist Pattern Removing Step S7)

Next, as shown in FIG. 3C, the above-mentioned resist pattern 3P is removed from the silicon substrate 1. The removal of the resist pattern 3P is performed, for example using a resist peeling liquid.

(Substrate Etching Step S8)

Next, as shown in FIG. 3(D), the silicon substrate 1 is dry-etched, using the hard mask pattern 2P as a mask. Specifically, the silicon substrate 1 is etched by a reactive ion etching (RIE) method. Thus, a projection/recess pattern 5 is formed on the silicon substrate 1 following the pattern shape of the hard mask pattern 2P. In this case, a portion dented by etching is a recess-shaped pattern 5a on the surface of the silicon substrate 1, and the other portion is a projection-shaped pattern 5b. Then, the projection/recess pattern 5 is formed as a whole by the combination of these patterns 5a and 5b.

(Hard Mask Pattern Removing Step S9)

Next, as shown in FIG. 3E, the hard mask pattern 2P is removed from the silicon substrate 1. The removal of the hard mask pattern 2P is performed by a chromium etching solution, when chromium is used for example as the hard mask material.

### 2. Explanation for the Characteristic Step

Subsequently, a substrate etching step S8 which is a characteristic step in the above-mentioned plurality of steps (S1 to S9) will be described in detail.

In the substrate etching step S8, a fluorine-based gas is used as the reactive gas of the etching gas used for dry-etching applied to the silicon substrate (silicon). Specifically, CF4 is used as an example of this reactive gas. Further, in the substrate etching step S8, a partial pressure of the CF4 being the fluorine-based gas is lowered by adding an inert gas to the etching gas. For example, an argon (Ar) gas is used as the inert gas. In this case, for example if a total flow rate of the etching gas introduced to an etching chamber of the RIE apparatus is 100 sccm, the flow rate (addition amount) of the argon gas is increased and the flow rate of the CF4 is decreased by an amount of increase, without changing the total flow rate (in other words, while maintaining a constant process pressure). Thus, the partial pressure of CF4 is lowered by the addition amount of the argon gas, compared with a case that the flow rate of CF4 is set to 100 sccm (in other words, in the case that the argon gas is not added).

Thus, it is confirmed as a result of the test performed by the inventors of the present invention, that when dry-etching is applied to the silicon substrate 1 by lowering the partial pressure of the CF4 by adding the argon gas to the etching gas used for the dry-etching applied to the silicon substrate 1, the verticality of the side face of the pattern 5 can be increased even if not lowering the process pressure. Thus, a sectional shape of the projection/recess pattern 5 can be formed into a rectangular shape or the shape closed to the rectangular shape, while avoiding a disadvantage caused by lowering the process pressure. Detailed explanation is given hereafter.

(Regarding an Etching Selection Ratio of the Mask Material and Silicon)

First, explanation is given for the etching selection ratio of the mask material and silicon.

In this embodiment, the total flow rate of the etching gas is not changed, although the partial pressure of the CF4 is lowered by adding the argon gas. Therefore, the process pressure becomes high, compared with the case that the process pressure is lowered by reducing the flow rate of the CF4. Generally, when the process pressure is increased, collapse of gas molecules in the etching chamber occurs frequently, and a mean free path of the gas molecules becomes short. Then, when ion is incident on the hard mask pattern 2P and the silicon substrate 1, energy in this case becomes relatively small. At this time, a chemical reaction between F-radical and silicon occurs spontaneously, without so much depending on the incident energy of the ion, etc. Therefore, even if the energy of the ion incident on the silicon substrate 1 is small, an etching amount of silicon is not changed so much. Meanwhile, when chromium, etc., is used for the mask material, a progress degree of etching applied to the mask material is changed, depending on the energy of the ion incident on the hard mask pattern 2P. Specifically, when the energy of the ion incident on the hard mask pattern 2P is relatively small, the progress degree of the etching applied to the mask material becomes small accordingly. As a result, the etching selectivity of the hard mask material and silicon becomes large.

(Regarding the Etching Rate for Silicon)

Next, the etching rate of silicon will be described.

When the argon gas is added to the etching gas, the following phenomenon occurs probably. Namely, when the argon gas is added to the etching gas, the argon gas is ionized in the etching chamber, to be turned into an argon ion. Then, decomposition of CF4 is accelerated due to existence of the argon ion in the etching chamber. Thus, the chemical reaction between F-radical and silicon generated by the decomposition of CF4, becomes activated, resulting in a high etching rate for silicon. Further, etching of silicon is also accelerated with an assistance of the argon ion. Therefore, even if the partial pressure of CF4 is lowered by adding the argon gas, the decrease of the etching rate for silicon can be suppressed.

Incidentally, in order to suppress the decrease of the etching rate for silicon, a mixing ratio of CF4 and argon gas in the etching chamber is preferably set as follows. Namely, when CF4 and the argon gas are introduced to the etching chamber as the etching gas, the flow rate (addition amount) of the argon gas is preferably set in a range of 4 to 10 times of the flow rate of CF4.

(Regarding Anisotropy of Etching)

Next, anisotropy of etching will be described.

When the partial pressure of CF4 is lowered by adding the argon gas to the etching gas, it is confirmed by the test performed by the inventors of the present invention, that the anisotropy of silicon during dry-etching is increased and as a result, the shape of the formed pattern 5 is close to a rectangular shape. However, the reason thereof has not been clear yet. In other words, there is a technical meaning of the present invention in confirming the above-described fact.

Further, the reason for increasing the anisotropy of etching by adding the argon gas, is as follows.

First, it is assumed that the flow rate of CF4 introduced into the etching chamber is the same in each case of the following (1) and (2).
(1) The case in which the process pressure is set to a first pressure, and under this setting condition, the partial pressure of CF4 is lowered by adding the argon gas to the etching gas.
(2) The case in which the process pressure is set to a second pressure lower than the first pressure without adding the argon gas to the etching gas.

In the case of (2), it is found that the verticality of ion incidence is increased by lowering the process pressure, and the anisotropy of etching becomes remarkable. Meanwhile, in the case of (1), the anisotropy is probably remarkable for the following reason. First, the dry-etching of silicon by RIE method is progressed by ion-etching and radical-etching. In the case of (1), the effect of the ion-etching is increased (in other words, the effect of the radical-etching is weakened) by lowering the partial pressure of CF4, and the anisotropy of etching is considered to be remarkable.

The verticality of the side face of the pattern 5 is the property of a surface shape, which means that a surface vertical to the surface (main surface) of the silicon substrate 1 is defined as a “vertical surface”, and whether or not the side face of the pattern 5 is close to the vertical surface. Specifically, as the verticality of the side face of the pattern is higher, the side face of the pattern 5 is closer to the vertical surface. Good or bad of the verticality of the side face of the pattern can be judged by an amount of side-etching. Specifically, the verticality of the side face of the pattern can be judged, with the following parameter as a reference, which is the parameter that varies depending on the amount of side-etching. Namely, good or bad of the verticality of the side face of the pattern can be judged depending on whether a difference between an opening dimension (a hole diameter in the case of a hole pattern, and a groove width in the case of a groove pattern) of an entrance portion of the projection-shaped pattern, and a dimension of an intermediate depth portion deeper than the opening dimension, is set in a previously determined allowable range. Also, good or bad of the verticality of the side face of the pattern can be judged depending on an angle formed by the side face of the recess-shaped pattern and the vertical surface, namely whether this angle is set in the previously determined allowable range.

### 3. Test Result

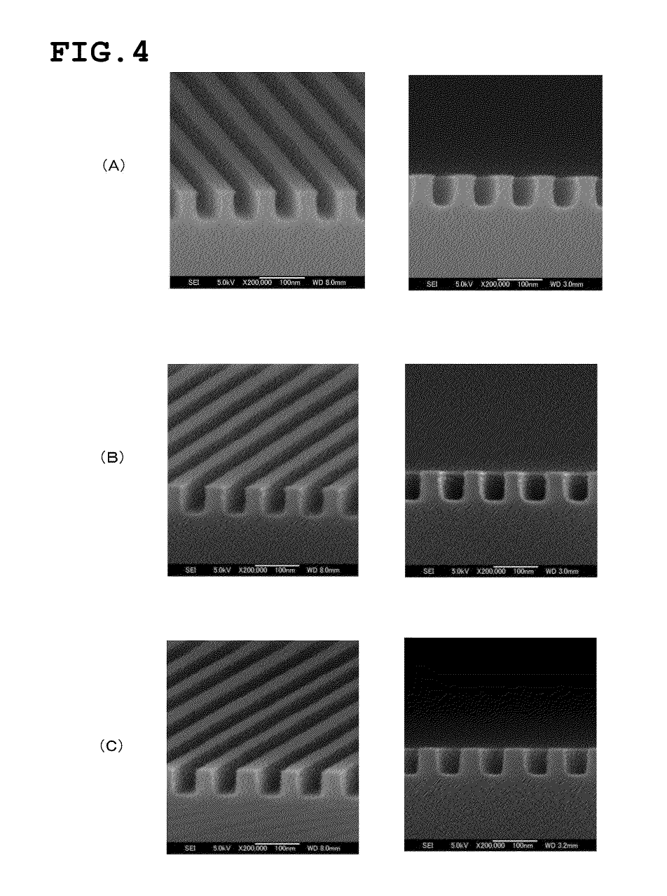

The above-described point is clarified by the result of the test performed by the inventors of the present invention. FIG. 4A to FIG. 4C show the shape of the pattern obtained by the result of the test. Note that in each of an upper stage, a middle stage, and a lower stage of the figures, a left side photograph and a right side photograph show the same pattern photographed from different directions. The result of each test will be described hereafter.

### Test Result 1

FIG. 4A shows the shape of the pattern obtained by etching the silicon substrate without adding the argon gas to the etching gas. In this test, patterning was performed to a metal layer made of CrN (chromium nitride) , to thereby form the hard mask pattern 2P, and thereafter a groove pattern with a pitch of 90 nm was formed on the silicon substrate 1, under a condition of the process pressure:5 Pa, an application voltage to the silicon substrate 1 (called “substrate bias” hereafter): 50W, and an etching time: 600 seconds, the total flow rate of the etching gas: 100 sccm, and the flow rate of CF4: 100 SCCM (100%).

### Test Result 2

FIG. 4(B) shows the shape of the pattern obtained by etching the silicon substrate by lowering the partial pressure of CF4 by adding the argon gas to the etching gas. In this test, patterning was performed to the metal layer made of CrN (chromium nitride), to thereby form the hard mask pattern 2P, and thereafter the groove pattern with a pitch of 90 nm was formed on the silicon substrate 1, under the condition of the process pressure:5 Pa, the substrate bias: 50W, the etching time: 600 seconds, the total flow rate of the etching gas: 100 sccm, the flow rate of CF4: 50 sccm (50%), and the flow rate of the argon gas: 50 sccm (50%).

### Test Result 3

FIG. 4C shows the shape of the pattern obtained by etching the silicon substrate by lowering the partial pressure of CF4 by adding the argon gas to the etching gas. In this test, patterning is performed to the metal layer made of CrN (chromium nitride), to thereby form the hard mask pattern 2P, and thereafter the groove pattern with a pitch of 90 nm was formed on the silicon substrate 1, under the condition of the process pressure:5 Pa, the substrate bias: 50W, the etching time: 600 seconds, the total flow rate of the etching gas: 100 sccm, the flow rate of CF4: 20 sccm (20%), and the flow rate of the argon gas: 80 sccm (80%).

As is clarified from the above-mentioned test result, the shape of the pattern is formed into a bowing shape as shown in FIG. 4(A) when the argon gas is not added to the etching gas. However, when the partial pressure of CF4 is lowered by adding the argon gas to the etching gas, the verticality of the side face of the pattern is increased as shown in FIG. 4(B) and FIG. 4(C), the shape of the pattern is close to the rectangular shape.

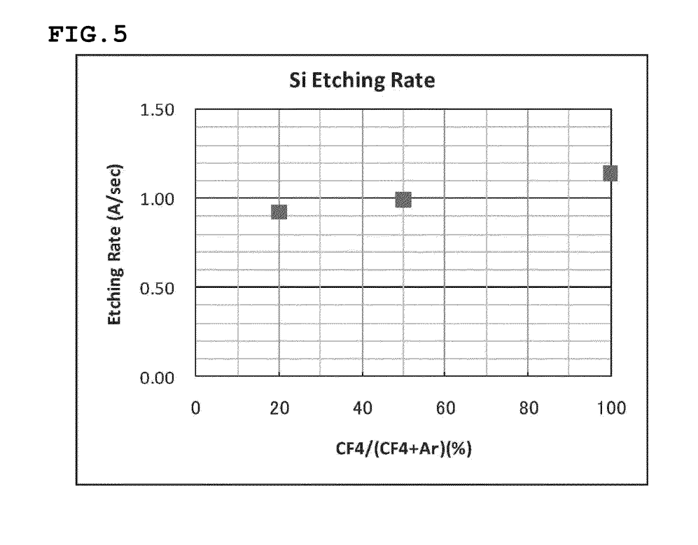

Further, FIG. 5 shows the above-mentioned test result, wherein the etching rate for silicon (A/sec) is taken on the vertical axis, and the mixing ratio of the CF4 and the argon gas is taken on the horizontal axis. As is clarified from this figure, when the mixing ratio of CF4 is set to be low such as 50% and 20%, the etching rate of silicon is decreased, compared with the case that the mixing ratio is set to 100%. However, the decrease of the etching rate is not remarkable so much. Specifically, when the mixing ratio of the CF4 is decreased to 50%, the decrease of the etching rate is within 10% or around, and even when the mixing ratio of the CF4 is decreased to 20%, the decrease of the etching rate is within 20% or around.

### 4. Effect of the Embodiment

According to the embodiment of the present invention, the following effect can be obtained.

Namely, when the projection/recess pattern 5 is formed on the surface of the silicon substrate 1, the partial pressure of the fluorine-based gas is lowered by adding the inert gas to the etching gas, and the dry-etching is applied to the silicon substrate 1. Therefore, even if not lowering the process pressure, the verticality of the side face of the pattern 5 can be increased. Accordingly, the sectional shape of the projection/recess pattern 5 can be formed into the rectangular shape or the shape close to the rectangular shape, without causing the decrease of the etching selectivity of the mask material and silicon, and the decrease of the etching rate for silicon. As a result, both of shortening the etching time and controlling the shape of the etching pattern (rectangular shape), can be achieved.

### 5. Modified Example, Etc.

Note that the technical range of the present invention is not limited to the above-mentioned embodiment, and includes an embodiment in which various modifications and improvements are added in a range capable of deriving a specific effect obtained by the constituting features of the invention and the combination thereof.

For example, according to the above-mentioned embodiment, the argon gas is used for the inert gas added to the etching gas in the substrate etching step S8. However, the present invention is not limited thereto, and for example a helium (He) gas can also be used. Further, the fluorine-based gas used for the reactive gas is not limited to CF4, and other fluorine-based gas that can be used for the etching of silicon, may also be used.

Further, when the inert gas is added to the etching gas, the addition amount of the inert gas may be continuously or gradually changed (increased or decreased) during the etching process from the beginning to the end, under the condition that the process pressure is fixed and the total flow rate of the etching gas is fixed.

Further, according to the above-mentioned embodiment, the resist pattern removing step S7 is provided between the hard mask pattern formation step S6 and the substrate etching step S8, in a series of the process regarding the substrate fabricating method. However, the present invention is not limited thereto, and the resist pattern removing step S7 may also be provided between the substrate etching step S8 and the hard mask pattern removing step S9.

Further, the substrate fabricating method described in the above-mentioned embodiment can be suitably applied to the case of manufacturing the mold for imprint. Particularly, when the present invention applied to the case of manufacturing the mold for imprint, the side face of the pattern is close to the vertical surface, thus easily separating the mold from a transferred substrate. Accordingly, the mold having an excellent releasability, can be obtained.

Further, the substrate fabricating method of the present invention can be applied to the purpose of use other than manufacturing the mold for imprint. Specifically, for example, the substrate fabricating method of the present invention can be applied to the manufacture of a photomask for a semiconductor device, manufacture of a semiconductor, Micro Electro Mechanical Systems (MEMS), sensor elements, an optical disc, optical components such as a diffraction grating and polarizers, etc., nano-devices, organic transistors, color filters, micro lens array, immunoassay chip, DNA separation chip, micro reactors, nano-bio devices, optical waveguides, optical filters, and photonic crystals, etc.

### DESCRIPTION OF SIGNS AND NUMERALS

1 Silicon substrate
2 Hard mask layer
2P Hard mask pattern
3 Resist layer
3P Resist pattern
5 Pattern

1. A method of manufacturing a mold for nano-imprint, for forming a projection/recess pattern on a surface of a silicon substrate, comprising:
etching a substrate to form the projection/recess pattern on the surface of the silicon substrate by applying dry-etching to the silicon substrate using a hard mask pattern as a mask, in a state of covering the surface of the silicon substrate with the hard mask pattern made of a chromium-based material; and
applying dry-etching to the silicon substrate in etching the substrate using a fluorine-based gas as a reactive gas of an etching gas used for the dry-etching applied to the silicon substrate, and adding an inert gas to the etching gas.

2. The method of manufacturing a mold for nano-imprint according to claim 1, wherein in etching the substrate, the inert gas is added so that a side face of a pattern obtained by applying dry-etching to the silicon substrate, is not formed into a bowing shape.

3. The method of manufacturing a mold for nano-imprint according to claim 1, wherein a flow rate of the inert gas is set in a range of 4 to 10 times of the flow rate of the fluorine-based gas.

4. The method of manufacturing a mold for nano-imprint according to claim 1, wherein in etching the substrate, dry-etching is applied to the silicon substrate in a state of lowering a partial pressure of the fluorine-based gas by adding the inert gas to the etching gas while maintaining a process pressure to be constant.

5. A substrate fabricating method, comprising:
etching a substrate for forming a projection/recess pattern on a surface of a silicon substrate, by applying dry-etching to the silicon substrate using a hard mask pattern as a mask in a state of covering the surface of the silicon substrate with the hard mask pattern; and
applying dry-etching to the silicon substrate in a state that a partial pressure of a fluorine-based gas is lowered by adding the inert gas to an etching gas compared with a case that an inert gas is not added, using the fluorine-based gas as a reactive gas of the etching gas used for the dry-etching applied to the silicon substrate.
